(19) United States
(12) Patent Application Publication
(10) Pub. No.: US 2026/0190386 A1
(43) Pub. Date: Jul. 2, 2026

(54) THREE-DIMENSIONAL SEMICONDUCTOR MEMORY ARRAY ARCHITECTURE AND MANUFACTURING METHOD THEREOF

(71) Applicant: PEKING UNIVERSITY, Beijing (CN)

(72) Inventors: Yimao CAI, Beijing (CN); Zongwei WANG, Beijing (CN); Jingwei SUN, Beijing (CN)

(21) Appl. No.: 18/860,025

(22) PCT Filed: Oct. 19, 2023
(86) PCT No.: PCT/CN2023/125377

§ 371 Date: Oct. 25, 2024

(30) Foreign Application Priority Data
May 23, 2023 (CN) 202310584815.8

(51) Int. Cl. H10D 30/67; G11C 5/06; H10B 51/20; H10B 61/00; H10B 63/00; H10B 63/10; H10D 30/01

(52) U.S. Cl. CPC H10D 30/6728; G11C 5/063; H10D 30/025; H10D 30/0318; H10D 30/6735; H10D 30/6755; H10B 51/20; H10B 61/22; H10B 63/10; H10B 63/34; H10B 63/84

(57) ABSTRACT

A three-dimensional semiconductor memory array architecture and a manufacturing method thereof is provided, which comprises: memory cells composed of novel memories and distributed in multiple layers in a vertical direction; vertical structures between adjacent memory cells, a vertical transistor is disposed in each of the vertical structures, one end of each novel memory is connected to a channel of the vertical transistor, another end is connected to a bit line BL in a horizontal direction, the channel of the vertical transistor is connected to a source line SL in the horizontal direction, a gate of the vertical transistor is wrapped by a gate dielectric material layer and a channel material layer and is disposed in a center of a corresponding vertical structure. The disclosure can meet requirements of material diversity, array reliability and process compatibility for the novel memories, is suitable for integration of large-scale novel memory arrays.

The present disclosure claims a priority to a patent application No. 202310584815.8, filed on May 23, 2023, entitled “THREE-DIMENSIONAL SEMICONDUCTOR MEMORY ARRAY ARCHITECTURE AND MANUFACTURING METHOD THEREOF”.

### TECHNICAL FIELD

The present disclosure relates to a technical field of hybrid integrated circuits of semiconductors and CMOS, and in particular to a three-dimensional semiconductor memory array architecture compatible with conventional CMOS processes and integrated with CMOS, and a manufacturing method thereof.

### BACKGROUND

With the rapid development of information technology, the amount of data in modern society has been growing rapidly. In order to efficiently store, access and calculate such a large amount of data, novel memories such as a resistive switching memory (RRAM), a phase change memory (PRAM), a magneto resistive memory (MRAM) and a ferroelectric memory (FeRAM) have received widespread attention and been researched.

The array architecture of the above-mentioned novel memories can usually be divided into three categories: 1R, 1S1R and 1T1R.

Among them, the 1R array refers to a crossbar (Crossbar or Crosspoint) array composed of the memory cells themselves. Although this type of array can achieve high-density stacking in structure, it has various problems such as leakage paths and write crosstalk, so the array size is usually small. In principle, it is not suitable for large-scale arrays.

The 1S1R array is a phase change memory array. It is based on the 1R array, and each memory cell is connected in series with a selector to suppress the leakage paths and the crosstalk to a certain extent. However, the material system of the selector is complex and fluctuates greatly, and although the selector device can improve the read voltage threshold of the memory, the leakage of the half-selector device is still serious. These problems limit the practical application of the 1S1R array.

The 1T1R array is a semiconductor memory array and is currently the most common array architecture. In this array architecture, transistors are used as the selecting unit of the memory, which completely shutting off the leakage path. However, the array density of the current 1T1R is limited by the density of transistors, and it is difficult to form a three-dimensional stacking structure like the 1S1R and 1R arrays, and the array density cannot be effectively improved.

### SUMMARY

In view of the above problems, an object of the present disclosure is to provide a three-dimensional semiconductor memory array architecture and a manufacturing method thereof, so as to improve the storage density of the 1T1R array architecture of novel memories such as resistive random access memory (RRAM), phase change memory (PRAM), magneto resistive memory (MRAM) and ferroelectric random access memory (FeRAM), and solve the problem such as the storage density of the memory array of the conventional architecture is difficult to improve.

The three-dimensional semiconductor memory array architecture provided by the present disclosure comprises memory cells composed of novel memories and distributed in multiple layers in a vertical direction; and vertical structures disposed between adjacent memory cells, wherein a vertical transistor is disposed in each of the vertical structures,
wherein one end of each of the novel memories is connected to a channel of the vertical transistor, and another end thereof is connected to a bit line BL in a horizontal direction;
wherein a channel of the vertical transistor is connected to a source line SL in the horizontal direction, and
wherein a gate of the vertical transistor is wrapped by a gate dielectric material layer and a channel material layer and is disposed in a center of a corresponding vertical structure.

In addition, an optional technical solution is that: wherein the source line SL comprises a column of transistors connected in series, and wherein gates of the column of transistors are connected to a corresponding word line WL.

In addition, an optional technical solution is that: wherein the word line WL connected to a gate of the vertical transistor is configured to control selecting of a channel of the vertical transistor.

In another aspect, the present disclosure further provides a method for manufacturing the three-dimensional semiconductor memory array architecture as described above, comprising:
S1: preparing, on a substrate, an isolation dielectric layer, a bit line BL and a source line SL which are alternately disposed, to form an alternate stack;
S2: photolithographically etching the alternating stack, to form a through hole as a vertical structure;
S3: preparing a novel memory structure at a position of the bit line BL;
S4: corroding redundant connection parts in the novel memory structure, to isolate each memory cell;
S5: preparing transistor channel material within the vertical structure, to form a transistor channel directly contacting an inner wall of the through hole;
S6: preparing and growing material of a transistor gate dielectric layer within the vertical structure to form a transistor gate dielectric layer directly contacting the transistor channel; and
S7: preparing gate material of a transistor within the vertical structure to form a transistor gate filled in the transistor gate dielectric layer.

In addition, an optional technical solution is that the preparing the novel memory structure at the position of the bit line BL includes: S31: corroding an edge of the bit line BL, to form a groove; and S32: preparing a novel memory material layer at a position of the groove to form the novel memory structure.

In addition, an optional technical solution is that the preparing the novel memory structure at the position of the bit line BL includes:
preparing the novel memory structure using a chemical reaction product of bit line material.

In addition, an optional technical solution is that: wherein, the isolation dielectric layer is made of silicon oxide SiO2 or a low dielectric constant material, and wherein a dielectric layer thickness of the isolation dielectric layer is 10 nm-1000 nm.

In addition, an optional technical solution is that: the bit line BL and the source line SL are made of metal tantalum (Ta), metal titanium (Ti), metal hafnium (Hf), metal palladium (Pd), metal cadmium (Cd), metal iridium (Ir), metal ruthenium (Ru), metal platinum (Pt), metal aluminum (Al) or metal nitrogen compound or doped polysilicon material or oxide conductor material, and the bit line BL and the source line SL are made of different materials, wherein a preparation process of the bit line BL and the source line DL is physical vapor deposition (PVD), plasma enhanced chemical vapor deposition (PECVD) or atomic layer deposition (ALD), and wherein a dielectric layer thickness of the bit line (BL) and the source line (SL) is 10 nm-1000 nm.

In addition, wherein an optional technical solution is that: the transistor channel material comprises IGZO and doped polysilicon, and wherein a preparation process of the transistor channel material comprises physical vapor deposition, atomic layer deposition and plasma enhanced chemical vapor deposition.

In yet another aspect, the present disclosure further provides a memory including the three-dimensional semiconductor memory array architecture as described above.

In the above-mentioned three-dimensional semiconductor memory array architecture, novel memories are three-dimensional horizontal stacked. By selecting ring-channel transistors in the vertical direction, novel memories in different layers can be accessed and operated. It is a three-dimensional non-volatile memory array architecture with high storage density and high reliability compatible with CMOS technology, which can meet the needs of material diversity, array reliability, and process compatibility for novel memories, as compared with the traditional planar two-dimensional memory array architecture. The manufacturing method of this three-dimensional semiconductor memory array architecture can increase the storage density to a level comparable to that of the current 3D-Nand Flash memory, far exceeding the array density of the current 1T1R, and is suitable for the integration of large-scale novel memory arrays.

In order to achieve the above and related purposes, one or more aspects of the present disclosure include features that will be described in detail later. The following description and the drawings describe some exemplary aspects of the present disclosure in detail. However, these aspects indicate only some of the various ways in which the principles of the present disclosure can be used. In addition, the present disclosure is intended to include all these aspects and their equivalents.

### BRIEF DESCRIPTION OF DRAWINGS

By referring to the following description in conjunction with the drawings, and with a more comprehensive understanding of the present disclosure, other objects and results of the present invention will become more apparent and easily understood. In the drawings:

FIG. 1 is a principle diagram of a circuit of a three-dimensional semiconductor memory array according to an embodiment of the present disclosure;

FIG. 2 is a cross-sectional view of a vertical structure of the three-dimensional semiconductor memory array according to an embodiment of the present disclosure;

FIG. 3 is a cross-sectional view of a horizontal structure of the three-dimensional semiconductor memory array according to an embodiment of the present disclosure;

FIG. 4 is a correspondence between a principle diagram and a structure diagram according to an embodiment of the present disclosure;

FIGS. 5 to 12 are schematic diagrams of a preparing process flow for a three-dimensional semiconductor memory array according to an embodiment of the present disclosure; wherein:

FIG. 5 is a cross-section of a structure after alternate preparation of an isolation dielectric layer, bit line material and source line material according to an embodiment of the present disclosure;

FIG. 6 is a structure of a vertical deep hole formed after a photolithographically etching according to an embodiment of the present disclosure;

FIG. 7 is a corroding process of a bit line structure according to an embodiment of the present disclosure;

FIG. 8 is a process of growing and preparing a novel memory structure according to an embodiment of the present disclosure;

FIG. 9 is a process of corroding and isolating the novel memory structure according to an embodiment of the present disclosure.

FIG. 10 is a process of growing and preparing a transistor channel material according to an embodiment of the present disclosure.

FIG. 11 is a process of growing and preparing transistor gate dielectric material according to an embodiment of the present disclosure.

FIG. 12 is a process of growing and preparing transistor gate material according to an embodiment of the present disclosure.

### DETAILED DESCRIPTION

In the following description, for purposes of explanation, numerous specific details are set forth in order to provide a thorough understanding of one or more embodiments. It will be apparent, however, that these embodiments may be practiced without these specific details. In other instances, well-known structures and devices are shown in block diagram form in order to facilitate describing one or more embodiments.

In the description of the disclosure, the line connected to the gate of the transistor is called a word line WL (Word Line), the line connected to the source of the transistor is called a source line SL (Source Line), and the line connected to one end of the device is called a bit line BL (Bit Line).

In order to describe the three-dimensional semiconductor memory array architecture and manufacturing method thereof in the present disclosure in detail, specific embodiments of the present disclosure will be described in detail below with reference to the drawings.

In order to improve the storage density of 1T1R array architecture of novel memories such as resistive random access memory (RRAM), phase change memory (PRAM), magneto resistive memory (MRAM) and ferroelectric memory (FeRAM), the present disclosure proposes a three-dimensional 1T1R (semiconductor memory) array architecture and a manufacturing method thereof, so as to increase the storage density of the 1T1R array to a level comparable to that of the current 3D-Nand Flash memory, far exceeding the array density of the current 1T1R.

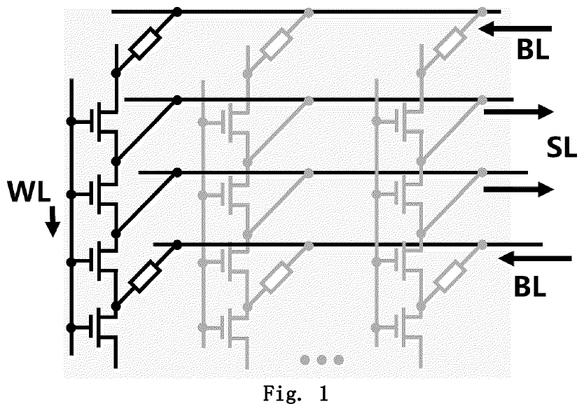

FIGS. 1 to 4 respectively illustrate the circuit principle, the cross-section of the vertical structure, the cross-section of the horizontal structure and the correspondence between the principle diagram and the structural diagram of a three-dimensional semiconductor memory array architecture according to an embodiment of the present disclosure.

As shown in FIGS. 1 to 4, the three-dimensional semiconductor memory array architecture provided by embodiments of the present disclosure includes memory cells composed of novel memories and distributed in multiple layers in a vertical direction; and vertical structures disposed between adjacent memory cells, wherein a vertical transistor is disposed in each of the vertical structures.

Wherein one end of each of the novel memories is connected to a channel of the vertical transistor, and another end thereof is connected to a bit line BL in a horizontal direction, wherein the channel of the vertical transistor is connected to a source line SL in the horizontal direction, and wherein a gate of the vertical transistor is wrapped by a gate dielectric material layer and a channel material layer and is disposed in a center of a corresponding vertical structure.

Specifically, FIG. 1 is a principle diagram of the three-dimensional semiconductor memory array architecture according to an embodiment of the present disclosure. As shown in FIG. 1, in the 1T1R array architecture proposed in the embodiment of the present disclosure, each source line SL comprises a column of transistors connected in series, and a corresponding word line WL is connected to gates of the column of transistors to control the switching states of the column of transistors.

Based on this three-dimensional semiconductor memory array architecture, if a read operation is to be performed on a single device, a read voltage is applied to the bit line BL of the row where the novel memory is located, and the remaining bit lines BL are floating; the source line SL adjacent to the novel memory is grounded, and the remaining source lines SL are floating. A voltage is applied to the word line WL corresponding to the novel memory to select it, and the current in the source line SL can be read, thereby realizing the read operation on the single device.

Taking the operation of resistive random access memory (RRAM) as an example, if a “SET” operation is intended to be performed on a single device, the method thereof is similar to the read operation. The voltage applied to the bit line BL where the memory is located is changed to the SET voltage, and the remaining bit lines BL are floating; the source line SL adjacent to the memory is grounded, and the remaining source lines SL are floating. At the same time, a voltage needs to be applied to the word line WL to select the transistor, so that the “SET” operation can be performed on the single device. If a “RESET” operation is intended to be performed, a RESET voltage is applied to the source line SL adjacent to the memory, and the remaining source lines SL are floating; the bit line BL of the row where the memory is located is grounded, and the remaining bit lines BL are floating, and then a voltage is applied to the word line WL to select the transistor, so that the “RESET” operation can be performed on the single device.

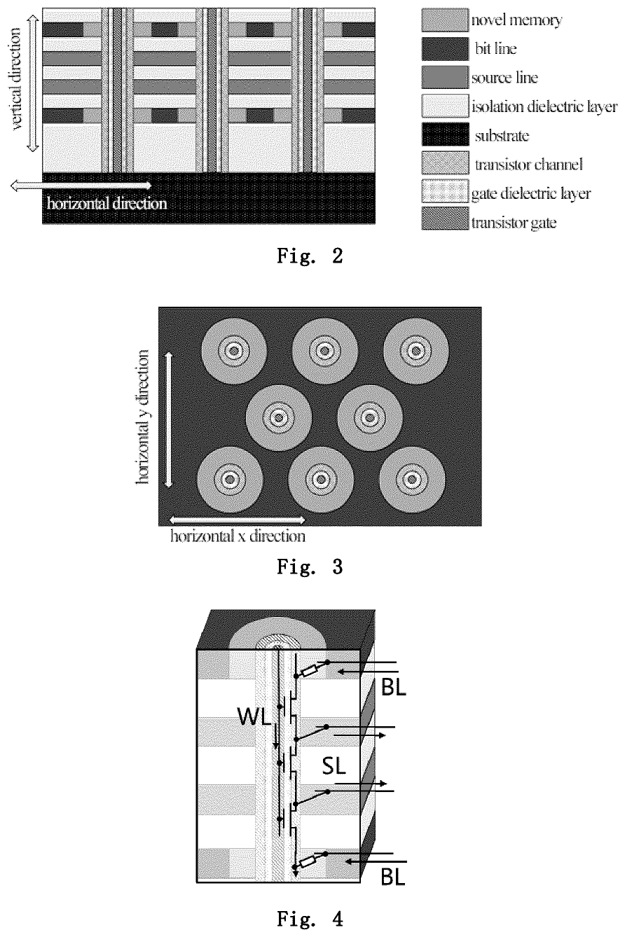

FIGS. 2 and 3 are respectively cross-sectional views of the vertical structure and horizontal structure of a three-dimensional semiconductor memory array architecture according to embodiments of the present disclosure. Among them, as shown in FIG. 2, one end of the multi-layer novel memory in the vertical direction is connected to the channel of the vertical transistor, and another end thereof is connected to the bit line BL in the horizontal direction. The channel of the vertical transistor is directly connected to the source line SL in the horizontal direction. The gate of the transistor is wrapped by a gate dielectric material layer and a channel material layer and is disposed in the center of the vertical structure. As shown in FIG. 3, the 1T1R multi-layer vertical structure can achieve high-density arrangement in the horizontal area.

FIG. 4 is a correspondence relationship between a principle diagram and a structural diagram according to an embodiment of the present disclosure. As shown in FIG. 4, the gate line WL connected to a gate of the vertical transistor and in the center of the vertical transistor is configured to control the selecting of the channel of the entire vertical transistor. Applying a voltage to the word line WL can select the transistor. After selecting, the novel memory of each layer can be accessed by the bit line BL of the layer.

The method for manufacturing the three-dimensional semiconductor memory array architecture as described above includes:

S1: Preparing, on a substrate, an isolation dielectric layer, a bit line BL and a source line SL which are alternately disposed, to form an alternate stack of the isolation dielectric layer, the bit line BL and the source line SL.

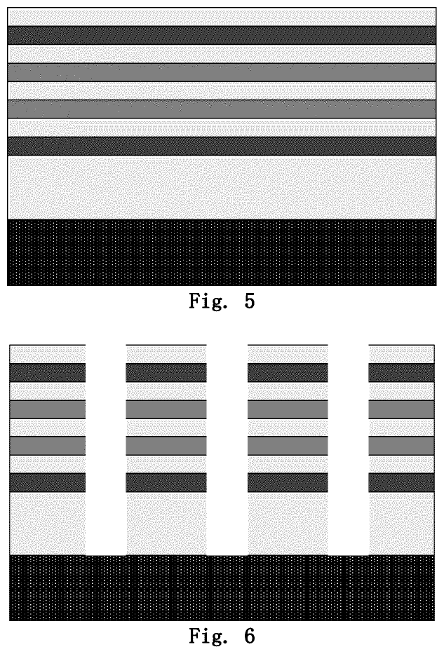

FIG. 5 is a cross-sectional view of a structure after alternate preparation of an isolation dielectric layer, bit line material and source line material according to an embodiment of the present disclosure. As shown in FIG. 5, the isolation dielectric layer, the bit line material, the isolation dielectric layer, the source line material, the isolation dielectric layer, the source line material, the isolation dielectric layer, the bit line material and the isolation dielectric layer are sequentially prepared on the substrate.

Among them, the isolation dielectric layer preferably includes silicon oxide SiO₂ or other low dielectric constant material (Low-K dielectrics), such as SiCOH, NDC or other material. The process for preparing the isolation dielectric layer may be chemical vapor deposition (CVD) and plasma enhanced chemical vapor deposition (PECVD), and the dielectric layer thickness of the isolation dielectric layer is 10 nm-1000 nm.

The bit line and source line are preferably metal tantalum Ta, metal titanium Ti, metal hafnium Hf, metal palladium Pd, metal cadmium Cd, metal iridium Ir, metal ruthenium Ru, metal platinum Pt, metal aluminum Al, etc. or metal nitride or doped polysilicon material or oxide conductor material, such as iridium oxide IrO, ruthenium oxide RuO, etc., wherein the bit line and source line may be made of different materials, and the wet etching selectivity may be high enough. The preferred preparation process for preparing bit line materials and source line materials is physical vapor deposition (PVD), plasma enhanced chemical vapor deposition (PECVD) or atomic layer deposition (ALD). The dielectric layer thickness of bit line material and source line material is 10 nm-1000 nm.

S2: Photolithographically etching all the alternating stacked layers prepared in step S1 to form a vertical through hole as a vertical structure of the three-dimensional semiconductor memory array architecture.

Among them, the photolithographically etching process is preferably dry etching, such as RIE (Reactive Ion Etching) and ICP (Inductively coupled plasma). Dry etching can physically remove materials on the substrate surface through ion bombardment, or convert substrate materials into unstable products through chemical reactions and then pump them away through air pumps. It is easier to perform anisotropic etching, which has high processing accuracy, and is suitable for micro-machining.

FIG. 6 is a cross-sectional view of the structure after photolithographically etching according to an embodiment of the present disclosure. As shown in FIG. 6, the vertical structures in the form of through holes divide the alternating stack into an infrastructure of individual memory cells.

S3: Preparing a novel memory structure at a position of the bit line BL of the alternating stack.

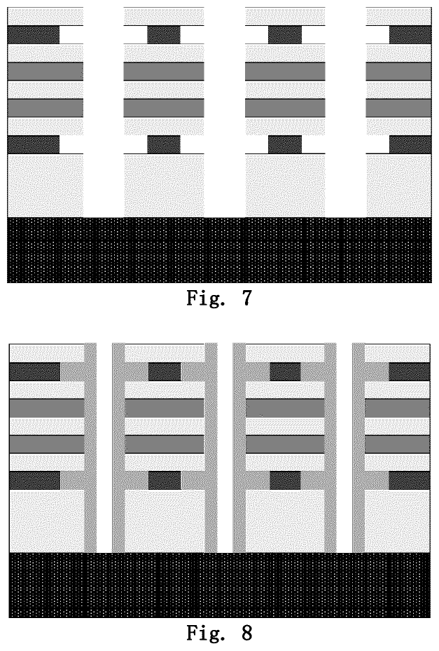

Among them, the novel memory structure may be prepared by corrosion or chemical reaction at the position of the bit line BL of the alternating stack. Specifically, as an example, FIG. 7 and FIG. 8 show cross-sectional views of preparing the novel memory structure at the position of the bit line BL of the alternating stack by corrosion. As shown in FIG. 7, the edge of the bit line BL is first corroded from the through hole to form a groove; then, as shown in FIG. 8, the novel memory material layer is prepared at the position of the groove to form the novel memory structure. The corrosion process in the corroding method is preferably wet corrosion.

In addition, the novel memory structure may also be prepared using a chemical reaction product of bit line material. For example, when the bit line material is tantalum (Ta), titanium (Ti), hafnium (Hf), aluminum (Al) or other metal material, the bit line material may be thermally oxidized to produce oxide such as tantalum oxide (TaOₓ), titanium oxide (TiOₓ), hafnium oxide (HfOₓ), and aluminum oxide (AlOₓ), which can be directly used as the novel memory structure.

In the process of preparing the novel memory structure, since the novel memory material layer may penetrate the entire through-hole structure, so that the memory cells are connected to each other, it is necessary to clear the redundant connection parts in the novel memory structure to isolate each memory cell.

In the present disclosure, the novel memory is preferably resistive random access memory (RRAM), phase change memory (PRAM), magneto resistive random access memory (MRAM), and ferroelectric random access memory (FeRAM).

Among them, the material of the resistive memory is preferably tantalum (Ta), tantalum oxide (TaOₓ), titanium (Ti), titanium oxide (TiOₓ), hafnium (Hf), hafnium oxide (HfOₓ), etc. The preparation process of the resistive memory is preferably oxidation, physical vapor deposition or atomic layer deposition;

The material of the phase change memory is preferably germanium antimony tellurium alloy (GeSbTe), CuGeTe alloy, GeSnTe alloy, YSbTe alloy or other phase change material. The preparation process of the phase change memory is preferably oxidation, physical vapor deposition or atomic layer deposition;

The material of the magneto resistive memory is preferably magnesium oxide MgO, aluminum oxide AlOₓ, etc., and the preparation process of the magneto resistive memory is preferably oxidation, physical vapor deposition or atomic layer deposition;

The material of the ferroelectric memory is preferably hafnium zirconium oxide (HfZrO), hafnium aluminum oxide (HfAlO), etc., and the preparation process of the ferroelectric memory is preferably physical vapor deposition or atomic layer deposition;

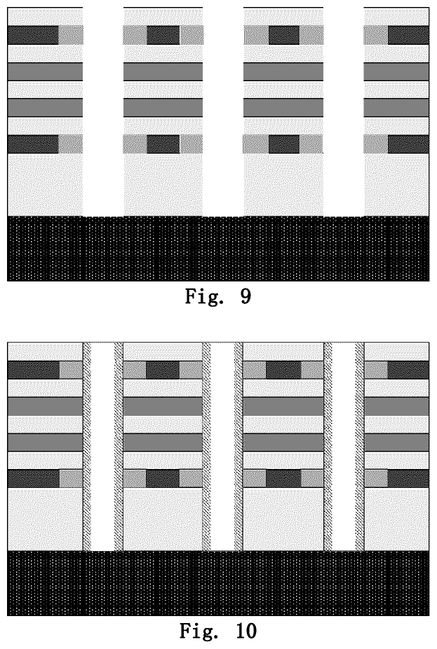

S4: Corroding the redundant connection parts in the novel memory structure, to isolate each memory cell. The cross-sectional view of the structure after corroding the redundant parts is shown in FIG. 9. The corroding process in the corroding method is preferably wet corroding.

S5: Preparing transistor channel material in the vertical structure, to form a transistor channel directly contacting the inner sidewall of the through hole. The cross section of the structure after preparing the transistor channel material is shown in FIG. 10.

Among them, the channel material is preferably a semiconductor oxide such as indium gallium zinc oxide IGZO, indium aluminum zinc oxide IAZO, indium tin zinc oxide ITZO or other multi-oxide semiconductor or polysilicon, doped polysilicon or other material, and the preparation process of the channel material is preferably PVD or ALD or plasma enhanced chemical vapor deposition PECVD.

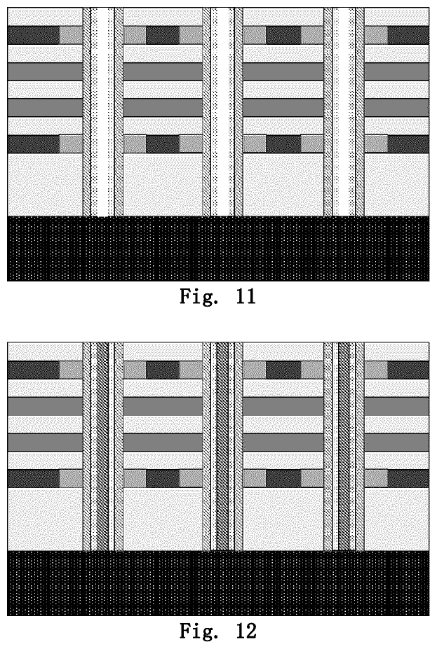

S6: Further preparing and growing material of a transistor gate dielectric layer within the vertical structure, to form a transistor gate dielectric layer directly contacting the transistor channel. Since the transistor channel has been prepared in the vertical structure, the material of the transistor gate dielectric layer is grown and prepared on the transistor channel. The cross-section of the structure after preparing and growing the material of the transistor gate dielectric layer is shown in FIG. 11.

Among them, material of growing the transistor gate dielectric layer is preferably HfO₂, SiO₂, Al₂O₃ and the like, and the preparation process for the material of growing the transistor gate dielectric layer is preferably atomic layer deposition ALD, chemical vapor deposition CVD or thermal oxidation.

S7: Further preparing the gate material of the transistor within the vertical structure to form a transistor gate filled in the transistor gate dielectric layer. Similarly, since the transistor channel and the grown transistor gate dielectric layer have been prepared and formed in the vertical structure, the gate material is prepared on the grown transistor gate dielectric layer. The cross-section of the structure after preparing the transistor gate material is shown in FIG. 12.

Here, the gate material is preferably doped polysilicon, and the preparation process is preferably plasma enhanced chemical vapor deposition PECVD.

Corresponding to the above three-dimensional semiconductor memory array architecture, the present disclosure further provides a memory including the above three-dimensional semiconductor memory array architecture. The specific embodiments of the memory can refer to the description in the three-dimensional semiconductor memory array architecture embodiment, which will not be repeated here.

The above mentioned three-dimensional semiconductor memory array architecture of the present disclosure is a high storage density and high-reliability three-dimensional non-volatile memory array architecture compatible with CMOS technology, which can effectively meet the requirements of novel memory for material diversity, array reliability, and process compatibility and can be used for the integration of large-scale novel memory arrays.

In the three-dimensional semiconductor memory array architecture provided by the present disclosure, novel memories are three-dimensional horizontal stacked, and the novel memories in different layers can be accessed and operated by selecting ring-channel transistors in the vertical direction. Compared with the traditional planar two-dimensional memory array architecture, this three-dimensional semiconductor memory array architecture can increase the storage density to a level comparable to that of the current 3D-Nand Flash memory, far exceeding the array density of the current 1T1R.

It should also be noted that in this specification, the terms “comprise”, “include” or any other variations thereof are intended to cover non-exclusive inclusion, so that a process, method, article or device including a series of elements includes not only those elements, but also other elements not explicitly listed, or also includes elements inherent to such process, method, article or device. In the absence of further restrictions, an element defined by the sentence “comprise” does not exclude the presence of other identical elements in the process, method, article or device including the element.

The above description of the disclosed embodiments enables those skilled in the art to make or use the present disclosure. Various modifications to these embodiments will be readily apparent to those skilled in the art, and the generic principles defined herein may be practiced in other embodiments without departing from the spirit or scope of the disclosure. Therefore, the present disclosure is not to be limited to the embodiments shown herein but is to be accorded the widest scope consistent with the principles and novel features disclosed herein.

1. A three-dimensional semiconductor memory array architecture, comprising:
memory cells composed of novel memories and distributed in multiple layers in a vertical direction; and
vertical structures disposed between adjacent memory cells, wherein a vertical transistor is disposed in each of the vertical structures,
wherein one end of each of the novel memories is connected to a channel of the vertical transistor, and another end thereof is connected to a bit line (BL) in a horizontal direction,
wherein the channel of the vertical transistor is connected to a source line (SL) in the horizontal direction, and
wherein a gate of the vertical transistor is wrapped by a gate dielectric material layer and a channel material layer and is disposed in a center of a corresponding vertical structure.

2. The three-dimensional semiconductor memory array architecture according to claim 1,
wherein the source line (SL) comprises a column of transistors connected in series, and
wherein gates of the column of transistors are connected to a corresponding word line (WL).

3. The three-dimensional semiconductor memory array architecture according to claim 2,
wherein the word line (WL) connected to a gate of the vertical transistor is configured to control selecting of a channel of the vertical transistor.

4. A method for manufacturing the three-dimensional semiconductor memory array architecture according to claim 1, comprising:
S1: preparing, on a substrate, an isolation dielectric layer, a bit line (BL) and a source line (SL) which are alternately disposed, to form an alternate stack;
S2: photolithographically etching the alternating stack, to form a through hole as a vertical structure;
S3: preparing a novel memory structure at a position of the bit line (BL);
S4: corroding redundant connection parts in the novel memory structure, to isolate each memory cell;
S5: preparing transistor channel material within the vertical structure, to form a transistor channel directly contacting an inner wall of the through hole;
S6: preparing and growing material of a transistor gate dielectric layer within the vertical structure, to form a transistor gate dielectric layer directly contacting the transistor channel; and
S7: preparing gate material of a transistor within the vertical structure, to form a transistor gate filled in the transistor gate dielectric layer.

5. The method for manufacturing the three-dimensional semiconductor memory array structure according to claim 4, wherein the preparing the novel memory structure at the position of the bit line (BL) comprises:
S31: corroding an edge of the bit line (BL), to form a groove; and
S32: preparing a novel memory material layer at a position of the groove, to form the novel memory structure.

6. The method for manufacturing the three-dimensional semiconductor memory array architecture according to claim 4, wherein preparing the novel memory structure at the position of the bit line (BL) comprises:
preparing the novel memory structure using a chemical reaction product of bit line material.

7. The method for manufacturing the three-dimensional semiconductor memory array architecture according to claim 4,
wherein the isolation dielectric layer is made of silicon oxide SiO₂ or low dielectric constant material, and
wherein a dielectric layer thickness of the isolation dielectric layer is 10 nm-1000 nm.

8. The method for manufacturing the three-dimensional semiconductor memory array architecture according to claim 4,
wherein the bit line (BL) and the source line (SL) are made of metal tantalum (Ta), metal titanium (Ti), metal hafnium (Hf), metal palladium (Pd), metal cadmium (Cd), metal iridium (Ir), metal ruthenium (Ru), metal platinum (Pt), metal aluminum (Al) or metal nitrogen compound or doped polysilicon material or oxide conductor material, and the bit line (BL) and the source line (SL) are made of different materials,
wherein a preparation process of the bit line (BL) and the source line (DL) is physical vapor deposition (PVD), plasma enhanced chemical vapor deposition (PECVD) or atomic layer deposition (ALD), and
wherein a dielectric layer thickness of the bit line (BL) and the source line (SL) is 10 nm-1000 nm.

9. The method for manufacturing a three-dimensional semiconductor memory array architecture according to claim 4,
wherein the transistor channel material comprises IGZO and doped polysilicon, and
wherein a preparation process of the transistor channel material comprises physical vapor deposition, atomic layer deposition and plasma enhanced chemical vapor deposition.

10. A memory comprising the three-dimensional semiconductor memory array architecture according to claim 1.
